(19) United States
(12) Patent Application Publication
(10) Pub. No.: US 2017/0242063 A1
(43) Pub. Date: Aug. 24, 2017

(54) BLOCK HEATER TEST SYSTEMS

(71) Applicants: Dan Kenneth Johnson, Camrose (CA); Jacki Johnson, Camrose (CA)

(72) Inventors: Dan Kenneth Johnson, Camrose (CA); Jacki Johnson, Camrose (CA)

(21) Appl. No.: 15/047,390

(22) Filed: Feb. 18, 2016

(51) Int. Cl. G01R 31/02; F02N 19/04

(52) U.S. Cl. CPC G01R 31/026; F02N 19/04

(57) ABSTRACT

A block heater test system for testing continuity in a vehicle's block heater. The block heater test system plugs into the power cord of a block heater to test continuity for the purpose of making sure the block heater can be powered. The block heater test system relies on batteries so no other power source is needed however alternate power sources can be used. An indicator light and/or audible tone indicates a fault in the block heater to the user. The small nature of block heater test system and the weather resident housing allow for easy use during inclement weather.

### BACKGROUND OF THE INVENTION

The following includes information that may be useful in understanding the present invention(s). It is not an admission that any of the information provided herein is prior art, or material, to the presently described or claimed inventions, or that any publication or document that is specifically or implicitly referenced is prior art.

1. Field of the Invention

The present invention relates generally to the field of automotive testing devices and more specifically relates to a block heater test system.

2. Description of Related Art

Many regions of the world experience extremely cold climates at certain times of the year. Engines are often equipped with block heaters in these regions. Many people in cold climate areas rely on block heaters to warm their vehicle's engine for the purpose of allowing a quicker start. These individuals use an electric heater element on the cylinder block connected with a power cord routed through the vehicle's grill. However, a convenient way to test the block heater before plugging it in to a power source may not be available for various reasons. In order to check if a block heater is functioning properly, a continuity check must be made. The equipment needed to successfully check continuity on a block heater may not be readily available. Being outside in extreme weather and not having access to or the knowledge to use a device for testing continuity can leave someone stranded in a potentially dangerous situation. Therefore, it is desirable to have a self-contained block heater tester that is easy to use and portable.

Several attempts have been made to solve the above-mentioned problems such as those found in U.S. Pat No. 5,784,015 to Stewart R. Duffin et al.; U.S. Pat No. 3,962,630 to Bertram Chaffee; and U.S. Pat. No. 4,249,125 to Clem Carver. International patents CA 2,149,997 to Michael J. Anka; and CA 2,007,630 to Michel Potvin. This art is representative of automotive testing devices. However, none of the above inventions and patents, taken either singly or in combination, is seen to describe the invention as claimed.

Preferably, an automotive block heater tester should provide a means to easily test the continuity of a vehicle's block heater in any weather condition and, yet would operate reliably and be manufactured at a modest expense. Thus, a need exists for a reliable block heater test system to avoid the above-mentioned problems.

### BRIEF SUMMARY OF THE INVENTION

In view of the foregoing disadvantages inherent in the known automotive testing devices art, the present invention provides a novel block heater tester system. The general purpose of the present invention, which will be described subsequently in greater detail is to provide a block heater tester that is useful for checking continuity in a block heater before connecting the block heater to a power source.

The block heater test system is disclosed herein, in a preferred embodiment, comprising: a block heater test assembly comprising: a housing having an outer surface comprising a female outlet, at least one indicator light, at least one activation switch, an inner volume, a power source, a wiring harness, and a rear cover comprising at least two attachment apertures. The housing comprises the outer surface, the inner volume, and the rear cover useful for housing internal components. The outer surface preferably comprises plastic to provide a non-conductive shell for preventing electrostatic discharge from occurring. The outer surface may comprise-a weather resistant coating and the inner volume comprises a waterproof seal. Other sealing means and combinations may be used.

The inner volume preferably comprises a vibration oscillator, and at least one speaker. The outer surface comprises the speaker volume control switch wherein the speaker emits at least one tone as an indicator of a working/non-working condition. The outer surface in preferred embodiments comprises the female outlet which is used to receive a block heater's male power supply plug, the indicator light is useful to identify a fault when connected to the block heater, and the activation switch is used for activation of the block heater test assembly. The female outlet preferably comprises a three-prong design. The female outlet comprises a common household receptacle. Other forms of connectors may be used.

The indicator light may comprise at least one light emitting diode. Other suitable light types may be used. The inner volume comprises the power source used for powering the block heater test assembly. The power source may be comprised of rechargeable batteries. Other suitable power sources may be used. The wiring harness transfers the power to the female outlet, the indicator light, and the activation switch. The rear cover is useful for enclosing the inner volume by at least two attachment apertures to marry the outer surface to the rear cover. The rear cover comprises at least two attachment apertures. The attachment apertures comprise clips. The block heater test system is structured and arranged for testing a block heater of a vehicle, and is able to be remotely used. In certain embodiments the wire comes from the ground port of the test device to a separate additional light/LED then connects to the main switch. This will identify that there is a short in the block heater cord in the event of the wires short out to the ground wire. For example: the green light turns on during test, continuity is good. Green and red light turns on together signifies a short in the system that is being tested.

A kit is also disclosed herein including: the block heater test assembly, batteries, and a set of user instructions.

A method of using a block heater test system is also disclosed herein comprising the steps of:

installing batteries into the block heater test assembly, connecting to a vehicle block heater plug, pressing the test button to test the vehicle block heater, viewing the indicator light to read the test result, and disconnecting the block heater test assembly. The method may further comprise the step of listening to a test tone.

The present invention holds significant improvements and serves as a block heater test system.

For purposes of summarizing the invention, certain aspects, advantages, and novel features of the invention have been described herein. It is to be understood that not necessarily all such advantages may be achieved in accordance with any one particular embodiment of the invention. Thus, the invention may be embodied or carried out in a manner that achieves or optimizes one advantage or group of advantages as taught herein without necessarily achieving other advantages as may be taught or suggested herein. The features of the invention which are believed to be novel are particularly pointed out and distinctly claimed in the concluding portion of the specification. These and other features, aspects, and advantages of the present invention will become better understood with reference to the following drawings and detailed description.

### BRIEF DESCRIPTION OF THE DRAWINGS

The figures which accompany the written portion of this specification illustrate embodiments and method(s) of use for the present invention, block heater test system, constructed and operative according to the teachings of the present invention.

FIG. 1 shows a perspective view illustrating a block heater test system during an ‘in-use’ condition showing a user testing a block heater according to an embodiment of the present invention.

FIG. 2 is a perspective view illustrating the block heater test system comprising a power switch, an indicator light, and a female outlet according to an embodiment of the present invention of FIG. 1.

FIG. 3 is a perspective view illustrating various components of the block heater test system according to an embodiment of the present invention of FIGS. 1-2.

FIG. 4 is a perspective view illustrating the block heater test system according to an embodiment of the present invention of FIGS. 1-3.

FIG. 5 is a flowchart illustrating a method of use for the block heater test system according to an embodiment of the present invention of FIGS. 1-4.

The various embodiments of the present invention will hereinafter be described in conjunction with the appended drawings, wherein like designations denote like elements.

### DETAILED DESCRIPTION

As discussed above, embodiments of the present invention relate to automotive testing devices and more particularly to a block heater test system as used to improve the testing of continuity in a vehicle's block heater.

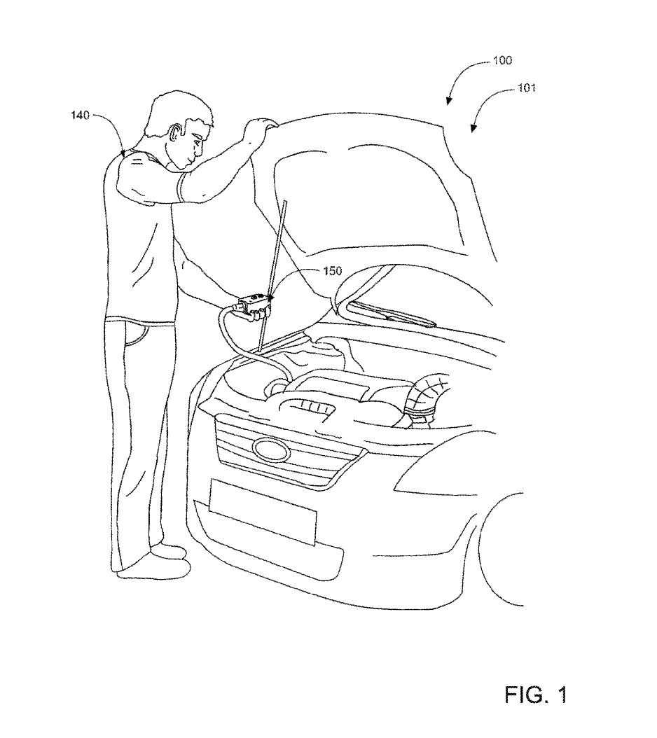

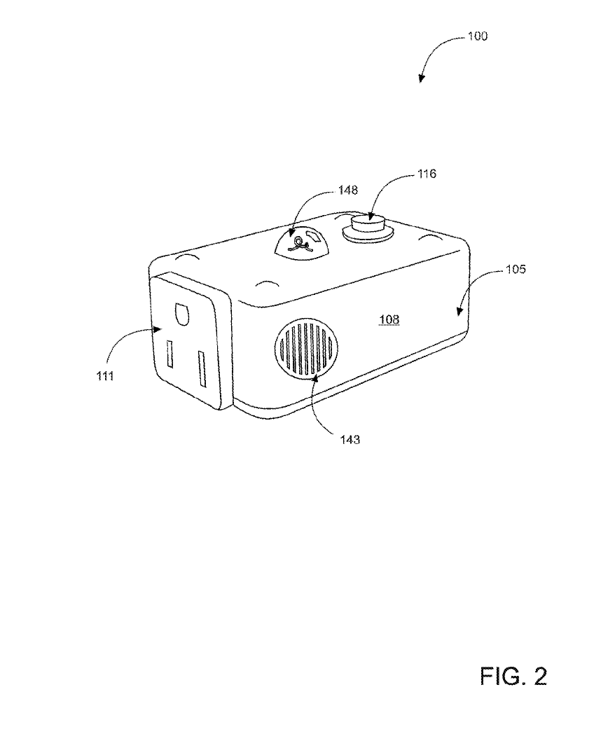

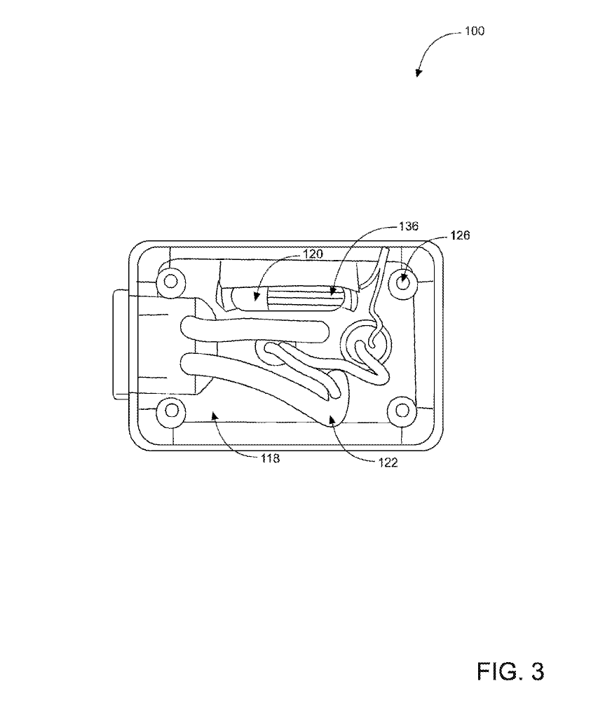

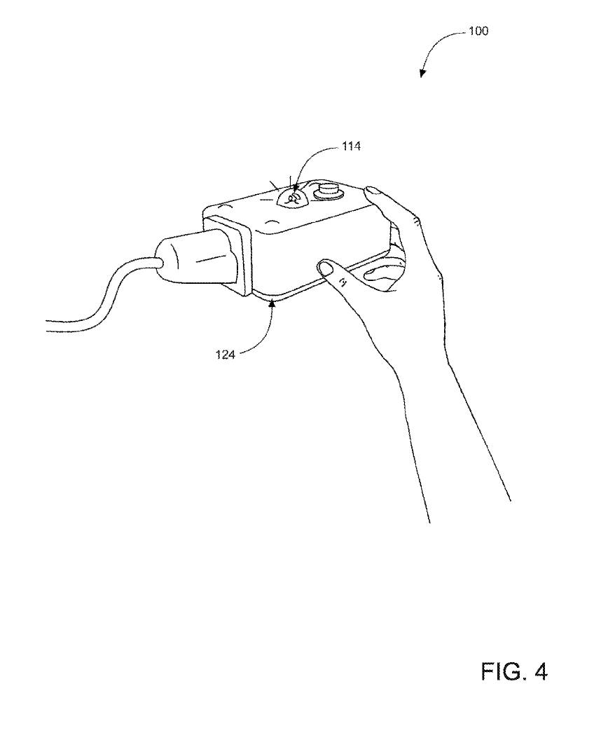

Referring to the drawings by numerals of reference there is shown in FIGS. 1-4 block heater test system 100 comprising: block heater test assembly 101. Block heater test assembly 101 comprises housing 105, inner volume 118, and rear cover 124. Housing 105 comprises outer surface 108, female outlet 111, at least one indicator light 114, and at least one activation switch 116. Inner volume 118 comprises: power source 120, wiring harness 122. Rear cover 124 comprising at least two attachment apertures 126. Outer surface 108 comprises female outlet 111 which is used to receive a block heater's male power supply plug, indicator light 114 useful to identify a fault when connected to the block heater, and at least one activation switch 116 used for activation of block heater test assembly 101. Inner volume 118 comprises power source 120 used for powering the block heater test assembly 101. Wiring harness 122 transfers the power to female outlet 111, indicator light 114, and activation switch 116. Rear cover 124 is useful for enclosing inner volume 118 by at least two attachment apertures 126 to housing 105 to rear cover 124.

Block heater test system 100 is structured and arranged for testing a block heater of vehicle 138. Block heater test assembly 101 may be comprised of at least one speaker 143. Outer surface 108 comprises plastic to provide a non-conductive shell to prevent electrostatic discharge from occurring. Female outlet 111 preferably comprises three-prong design. Outer surface 108 may be comprised of a speaker 143 volume control. Power source 120 comprises batteries 136. Power source 120 comprises a cigarette lighter port adaptor from the vehicle. Indicator light 114 comprises at least one light emitting diode 148. Outer surface 108 comprises weather resistant coating.

Inner volume 118 comprises a waterproof seal. Speaker 143 emits at least one tone as an indicator of a working/non-working condition. Inner volume 118 comprises a vibration oscillator. Rear cover 128 comprises at least two attachment apertures 126. Attachment apertures 126 comprises clips. Female outlet 111 comprises a female outlet. Block heater test assembly 101 is able to be remotely used.

Block heater test system 100 may be sold as kit 440 comprising the following parts: at least one block heater test assembly 101 at least one set of batteries 136; and at least one set of user instructions. The kit has instructions such that functional relationships are detailed in relation to the structure of the invention (such that the invention can be used, maintained, or the like in a preferred manner). Block heater test system 100 may be manufactured and provided for sale in a wide variety of sizes and shapes for a wide assortment of applications. Upon reading this specification, it should be appreciated that, under appropriate circumstances, considering such issues as design preference, user preferences, marketing preferences, cost, structural requirements, available materials, technological advances, etc., other kit contents or arrangements such as, for example, including more or less components, customized parts, different powering combinations, parts may be sold separately, etc., may be sufficient.

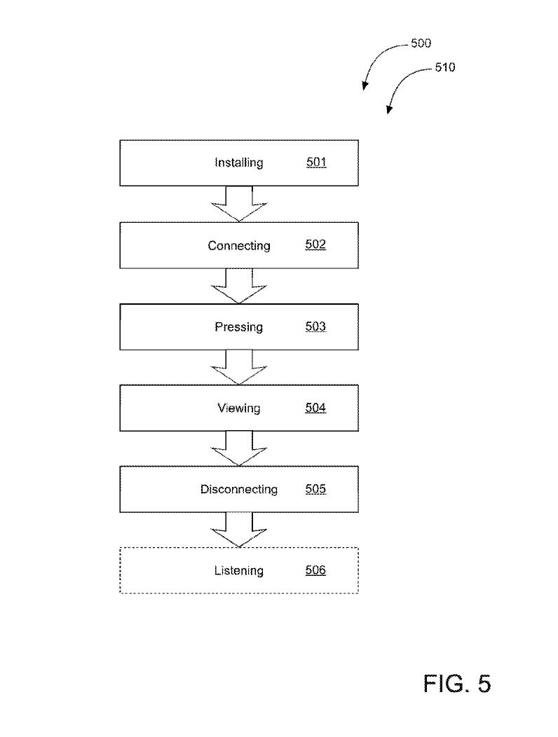

Referring now to FIG. 5 showing flowchart 550 illustrating method of use 500 for block heater test system 100 according to an embodiment of the present invention of FIGS. 1-4. As shown, method of use 500 may comprise the steps of: step one 501, installing batteries 136 into block heater test assembly, step two 502 connecting to a vehicle block heater plug, step three 503 pressing the test button 116 to test the vehicle block heater, step four 504 viewing the indicator light to read the test result, and step five 505 disconnecting the block heater test assembly. Optional steps of method of use 500 are illustrated using dotted lines in FIG. 5 so as to distinguish them from the other steps of method of use 500.

It should be noted that the steps described in the method of use can be carried out in many different orders according to user preference. The use of “step of” should not be interpreted as “step for”, in the claims herein and is not intended to invoke the provisions of 35 U.S.C. §112, 6. Upon reading this specification, it should be appreciated that, under appropriate circumstances, considering such issues as design preference, user preferences, marketing preferences, cost, structural requirements, available materials, technological advances, etc., other methods of use arrangements such as, for example, different orders within above-mentioned list, elimination or addition of certain steps, including or excluding certain maintenance steps, etc., may be sufficient.

The embodiments of the invention described herein are exemplary and numerous modifications, variations and rearrangements can be readily envisioned to achieve substantially equivalent results, all of which are intended to be embraced within the spirit and scope of the invention. Further, the purpose of the foregoing abstract is to enable the U.S. Patent and Trademark Office and the public generally, and especially the scientist, engineers and practitioners in the art who are not familiar with patent or legal terms or phraseology, to determine quickly from a cursory inspection the nature and essence of the technical disclosure of the application.

What is claimed is new and desired to be protected by Letters Patent is set forth in the appended claims:

1. A block heater test system comprising:
a block heater test assembly comprising;
a housing having;
an outer surface comprising;
a female outlet;
at least one indicator light;
at least one activation switch;
an inner volume comprising;
a power source; and
a wiring harness; and
a rear cover comprising;
at least two attachment apertures;
wherein said block heater test system comprises said block heater test assembly;
wherein said block heater test assembly comprises said housing;
wherein said housing comprises said outer surface, said inner volume, and said rear cover useful for housing internal components;
wherein said outer surface comprises said female outlet which is used to receive a block heater's male power supply plug, said indicator light useful to identify a fault when connected to said block heater, and said at least one activation switch used for activation of said block heater test assembly;
wherein said inner volume comprises said power source and said wiring harness wherein said power source is used for powering said block heater test assembly;
wherein said wiring harness transfers power to said female outlet, said indicator light, and said activation switch;
wherein said rear cover is useful for enclosing said inner volume by at least two attachment apertures to marry said outer surface to said rear cover; and
wherein said block heater test system is structured and arranged for testing a block heater of a vehicle.

2. The block heater test system of claim 1 wherein said block heater test assembly comprises at least one speaker.

3. The block heater test system of claim 1 wherein said outer surface comprises plastic to provide a non-conductive shell to prevent electrostatic discharge from occurring.

4. The block heater test system of claim 3 wherein said female outlet comprises at least two connectors.

5. The block heater test system of claim 3 wherein said outer surface comprises a speaker and a volume control switch.

6. The block heater test system of claim 1 wherein said power source comprises rechargeable batteries.

7. The block heater test system of claim 6 wherein said power source comprises a cigarette lighter port adaptor from said vehicle.

8. The block heater test system of claim 1 wherein said indicator light comprises at least one light emitting diode.

9. The block heater test system of claim 3 wherein said outer surface comprises weather resistant coating.

10. The block heater test system of claim 1 wherein said inner volume comprises a waterproof seal.

11. The block heater test system of claim 2 wherein said speaker emits at least one tone as an indicator of a working/non-working condition.

12. The block heater test system of claim 1 wherein said inner volume comprises a vibration oscillator.

13. The block heater test system of claim 10 wherein said rear cover comprises at least two attachment apertures.

14. The block heater test system of claim 13 wherein said attachment apertures comprise clips.

15. The block heater test system of claim 4 wherein said female outlet comprises an American common household receptacle.

16. The block heater test system of claim 1 wherein said heater test assembly is able to be remotely used.

17. A block heater test system comprising:
a block heater test assembly comprising;
a housing having;
an outer surface comprising;
a female outlet;
at least one indicator light;
at least one activation switch;
an inner volume;
a power source; and
a wiring harness;
a rear cover comprising;
at least two attachment apertures;
wherein said block heater test system comprises said block heater test assembly;
wherein said block heater test assembly comprises said housing;
wherein said housing comprises said outer surface, said inner volume, and said rear cover useful for housing internal components;
wherein said outer surface comprises plastic to provide a non-conductive shell to prevent electrostatic discharge from occurring;
wherein said outer surface comprises weather resistant coating;
wherein said inner volume comprises a waterproof seal;
wherein said inner volume comprises vibration oscillator;
wherein said block heater test assembly comprises at least one speaker;
wherein said outer surface comprises said speaker volume control switch;
wherein said speaker emits at least one tone as an indicator of a working/non-working condition;
wherein said outer surface comprises said female outlet which is used to receive a block heater's male power supply plug, said indicator light useful to identify a fault when connected to said block heater, and said at least one activation switch used for activation of said block heater test assembly;
wherein said female outlet comprises a three-prong design;
wherein said female outlet comprises a common household receptacle;
wherein said indicator light comprises at least one light emitting diode;
wherein said inner volume comprises said power source used for powering said block heater test assembly;
wherein said power source comprises rechargeable batteries;
wherein said power source comprises an adapter for an external power source wherein and said wiring harness transfers said power to said female outlet, said indicator light, and said activation switch;
wherein said rear cover is useful for enclosing said inner volume by at least two attachment apertures to marry said outer surface to said rear cover;
wherein said rear cover comprises at least two attachment apertures;
wherein said attachment apertures comprise clips;
wherein said block heater test system is structured and arranged for testing a block heater of a vehicle; and
wherein said heater test assembly is able to be remotely used.

18. The block heater test system of claim 17 further comprising a kit including: said block heater test assembly, batteries, and a set of user instructions.

19. A method of using a block heater test system comprising the steps of:
installing batteries into the block heater test assembly;
connecting to a vehicle block heater plug;
pressing the test button to test the vehicle block heater;
viewing the indicator light to read the test result; and
disconnecting the block heater test assembly.

20. The method of claim 19 further comprising the step of:
listening to a test tone.
